(19) United States
(12) Patent Application Publication
(10) Pub. No.: US 2025/0015206 A1
(43) Pub. Date: Jan. 9, 2025

(54) Light Sensing Device Packaging Structure and Packaging Method thereof

(71) Applicant: SENSORTEK TECHNOLOGY CORP., Hsinchu County (TW)

(72) Inventor: Wen-Chieh Tsou, Hsinchu County (TW)

(21) Appl. No.: 18/739,901

(22) Filed: Jun. 11, 2024

Related U.S. Application Data
(60) Provisional application No. 63/472,033, filed on Jun. 9, 2023.

(51) Int. Cl. H01L 31/0216; H01L 25/16; H01L 31/0203; H01L 31/18

(52) U.S. Cl. CPC H01L 31/02162; H01L 25/167; H01L 31/0203; H01L 31/18

(57) ABSTRACT

The present invention discloses a light sensing device packaging structure and the packaging method thereof. The packaging structure comprises a substrate, a transparent molding substance, a first glass, and a sheltering element. A first optical element and a second optical element are disposed on the substrate. The transparent molding substance covers the first optical element and the second optical element. A bottom surface of the first glass is fixed on the transparent molding substance and aligned with the first optical element. The sheltering element covers the edge of the transparent molding substance not covered by the first glass. This design maintains the excellent optical sensing effect of the light sensing device while allowing for miniaturization of the overall structure.

### FIELD OF THE INVENTION

The present application relates to a package structure and a packaging method thereof, in particular to a light sensing device packaging structure with glass and a packaging method thereof.

### BACKGROUND OF THE INVENTION

Light sensing devices, such as proximity sensors (PS) and ambient light sensors (ALS) are widely used in portable mobile devices, for example, mobile phones or other consumer electronic devices. Both proximity sensors and ambient light sensors require light sensing devices while proximity sensors generally also require light emitting devices (such as infrared emitters or laser light emitters).

In order to provide good optical sensing effects, some light sensing devices need to be equipped with optical filters corresponding to light emitting devices or photosensitive devices. The easiest way to implement optical filters is to make them on glass by coating. An existing packaging method for a light sensing device with glass is to fix the glass on the cover of the light sensing device. However, as the circuit area and sensor size decrease, the structure of the cover and glass will also be miniaturized accordingly. Due to the limitations of molding capabilities, the difficulty of fixing the miniaturized glass on the miniaturized cover made by injection molding and other methods will be greatly increased. Besides, it is also easy for the glass to fall off.

Based on the above deficiencies, it is necessary to provide a packaging structure and packaging method for light sensing devices such as proximity sensors and ambient light sensors to achieve the purposes of maintaining excellent optical sensing effects and miniaturizing the whole structure, thus meeting the needs of practical applications.

### SUMMARY OF THE INVENTION

An objective of the present invention is to provide a light sensing device packaging structure and the packaging method thereof. In particular, for a light sensing device packaging structure with glass, by fixing the glass on a transparent molding substance, the problem of difficulty in fixing the glass according to the prior art is effectively avoided. The glass will not fall easily as in the prior art, and the excellent optical sensing effect of the light sensing device can be maintained, thus achieving the purpose of miniaturizing the overall structure.

The present invention discloses a light sensing device packaging structure, which comprises a substrate, a transparent molding substance, a first glass, and a sheltering element. A first optical element and a second optical element are disposed on the substrate. The transparent molding substance covers the first optical element and the second optical element. A bottom surface of the first glass is fixed on the transparent molding substance and aligned with the first optical element. The sheltering element covers the edge of the transparent molding substance not covered by the first glass.

The present invention further discloses a light sensing device packaging method, which comprises steps of: disposing a first optical element and a second optical element on a substrate; covering the first optical element and the second optical element within a transparent molding substance; precutting the transparent molding substance to create a groove space; fixing a bottom surface of a first glass on the transparent molding substance and aligning with the first optical element; and filling an opaque glue material into the groove space and solidifying the opaque glue material to form a sheltering element. The sheltering element covers the edge of the transparent molding substance not covered by the first glass.

### BRIEF DESCRIPTION OF DRAWINGS

FIG. 1 shows a cross-sectional view of the light sensing device packaging structure according to the first embodiment of the present invention;

FIG. 2 shows a flowchart of the light sensing device packaging method according to an embodiment of the present invention;

FIG. 3 shows the step of filling opaque glue material by glue dispensing in the packaging method according to an embodiment of the present invention;

FIG. 4 shows the step of filling opaque glue material by injecting glue via a mold in the packaging method according to an embodiment of the present invention;

FIG. 5A shows a schematic diagram of disposing the coating layer in the light sensing device packaging structure according to an embodiment of the present invention;

FIG. 5B shows another schematic diagram of disposing the coating layer in the light sensing device packaging structure according to an embodiment of the present invention;

FIG. 6 shows a schematic diagram of various glass structures for the light sensing device packaging structure according to an embodiment of the present invention; and

FIG. 7 shows a cross-sectional view of the light sensing device packaging structure according to the second embodiment of the present invention.

### DETAILED DESCRIPTION OF THE INVENTION

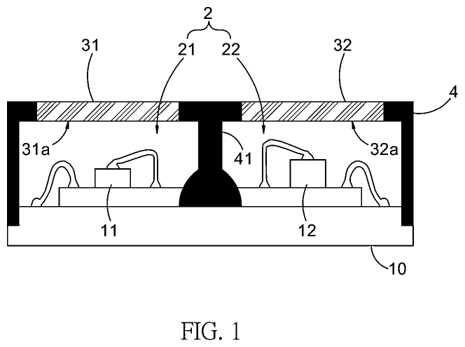

FIG. 1 shows a cross-sectional view of the light sensing device packaging structure according to the first embodiment of the present invention. The light sensing device packaging structure comprises a substrate 10, a first optical element 11, a second optical element 12, a transparent molding substance 2, a first glass 31, and a sheltering element 4. The first optical element 11 and the second optical element 12 may be a light emitting device or a photosensitive device, respectively. Generally, the light emitting device is an infrared emitter or a laser emitter. The photosensitive device is typically an application specific integrated circuit (ASIC) fabricated by integrated circuit processes and might include photosensitive devices and operational circuits (for example, the photosensitive device and the operation circuit of a proximity sensor and/or an ambient light sensor).

To elaborate, if the light sensing device packaging structure is used as a proximity sensor, then the proximity sensor normally includes one or more light emitting devices and a photosensitive device. Thus, the first optical element 11 and the second optical element 12 may be a light emitting device and a photosensitive device, respectively. Alternatively, for a portion of the proximity sensor or other light sensing device, to provide specific functions, it is required to have multiple light emitting devices with different wavelengths. Hence, the first optical element 11 and the second optical element 12 may both be light emitting devices, respectively. If the light sensing device packaging structure is an ambient light sensor, for a portion of the ambient light sensor, in order to sense some advanced optical properties such as color temperature, multiple photosensitive devices will be required with each photosensitive device accompanied by a different optical filter. Thus, the first optical element 11 and the second optical element 12 may both be photosensitive devices, respectively. Of course, if a proximity sensor and an ambient light sensor are integrated in the light sensing device packaging structure, it generally includes two light emitting devices and one photosensitive device. Consequently, the optical elements disposed in the light sensing device packaging structure are not limited to the first optical element 11 and the second optical element 12.

As shown in FIG. 1, the first optical element 11 and the second optical element 12 are disposed on the substrate 10. The first optical element 11 and the second optical element 12 may be connected to the substrate 10 by wire bonding. In addition, they may be connected to the substrate 10 through other methods. The present invention is not limited to wire bonding. According to an embodiment, the substrate 10 is a copper substrate, a ceramic substrate, a lead frame, a resin substrate, or a printed circuit board. The wire for wire bonding may be, but is not limited to, a gold wire.

The first optical element 11 and the second optical element 12 are covered and sealed within a transparent molding substance 2. The first glass 31 and the second glass 32 are fixed on the transparent molding substance 2, respectively. To elaborate, the first glass 31 includes a bottom surface 31a. The bottom surface 31a of the first glass 31 may be attached and fixed on the transparent molding substance 2 and aligned with the first optical element 11. The second glass 32 includes a bottom surface 32a. The bottom surface 32a of the second glass 32 may be attached and fixed on the transparent molding substance 2 and aligned with the second optical element 12.

The first glass 31 and the second glass 32 can be used to fabricate optical filters. For example, by using the coating method, the first glass 31 and the second glass 32 may form optical filters that allow light passage of specific wavelengths or polarization. Optical filters may be formed by stacking different materials on the first glass 31 and the second glass 32. For example, a single-layer or multi-layer coating or optical microstructure may be used to fabricate the optical filter. Alternatively, the optical filter may be formed by doping dyes into the first glass 31 and the second glass 32. Of course, the optical filter may be a mixture of the above two structures.

The sheltering element 4 is made of opaque materials. In addition, the sheltering element 4 may cover the edge of the transparent material 2 not covered by the first glass 31 and the second glass 32 while maintaining the first glass 31 and the second glass 32 exposed. Given the limited space, to reduce crosstalk between the first glass 31 and the second glass 32, a wall 41 of the sheltering element 4 is formed between the first optical element 11 and the second optical element 12 to avoid light transmission between them. Under such a situation, the transparent molding substance 2 is divided into a first part 21 and a second part 22 by the wall 41. The first part 21 seals the first optical element 11, and the first glass 31 is fixed on the first part 21. The second part 22 seals the second optical element 12, and the second glass 32 is fixed on the second part 22.

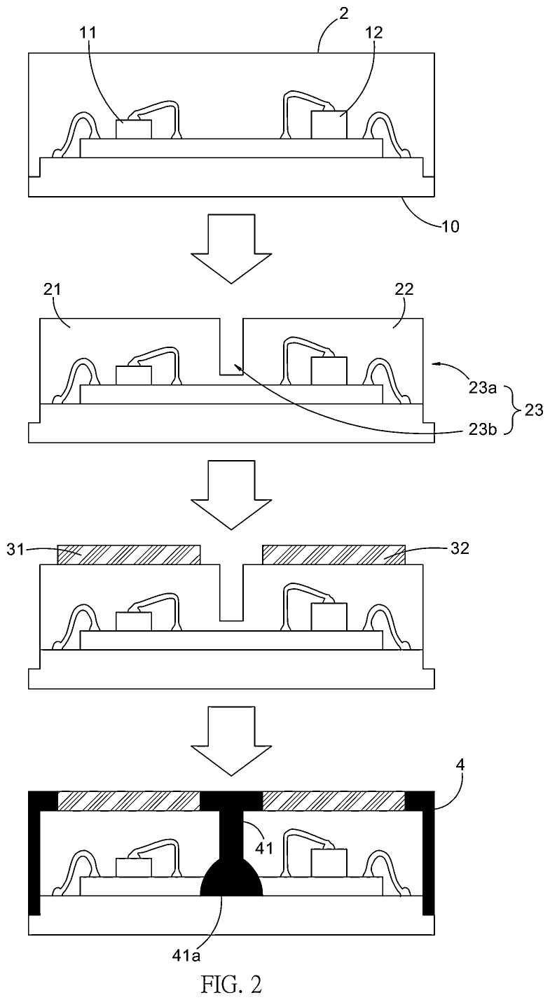

The following will illustrate how to fabricate the light sensing device packaging structure according to the first embodiment of the light sensing device packaging structure and the packaging method thereof of the present invention. FIG. 2 shows a flowchart of the light sensing device packaging method according to an embodiment of the present invention.

Cover and seal the first optical element 11 and the second optical element 12 within a transparent molding substance 2. For example, inject a liquid transparent glue material (such as transparent resin) into a mold. After solidification, it forms the transparent molding substance 2. After removing the mold, the first optical element 11 and the second optical element 12 are then covered within the transparent molding substance 2.

Next, precut the transparent molding substance 2 to reserve the groove space 23 for disposing the sheltering element 4. To elaborate, since the light sensing device packaging structure preferably adopts the panelization process, it is difficult to reserve the first groove space 23a for the sheltering element 4 by forming the transparent molding substance 2 by molds only. Therefore, it is necessary to execute this precut step to create the corresponding first groove space 23a. Besides, the transparent molding substance 2 formed by molds might not be flat enough to attach and fix the first glass 31 and the second glass 32. Therefore, this precut step may solve the problem of surface flatness on the transparent molding substance 2. Moreover, if the wall 41 is formed between the first optical element 11 and the second optical element 12, this precut step may add a second groove space 23b on the transparent molding substance 2 for disposing the wall 41. The second groove space 23b separates the transparent molding substance 2 into the first part 21 and the second part 22.

By using a transparent glue material (for example, transparent adhesive) or other fixing means, the first glass 31 and the second glass 32 are fixed on the transparent molding substance 2. It should be noted that if the location of the glasses requires no cutting and the risk of damaging the first glass 31 and the second glass 32 by the cutting tool is not a concern, the order of fixing the glasses and the above-mentioned precut step may be switched.

Fill the opaque glue material into the groove space 23 formed by the above-mentioned precut. After solidification and cutting and grinding the redundant parts, the opaque glue material forms the sheltering element 4. As described above, the sheltering element 4 covers the edge of the transparent molding substance 2 not covered by the first glass 31 and the second glass 32 while maintaining the first glass 31 and the second glass 32 exposed. The opaque glue material according to the present embodiment is epoxy, silica glue, a mixture of resin and silica glue, or acrylic glue. In addition, the opaque glue materials may be made opaque by doping with dyes, carbon black, silicon dioxide, or titanium dioxide. Therefore, the sheltering element 4 formed by solidification of the opaque glue material has the effect of sheltering light.

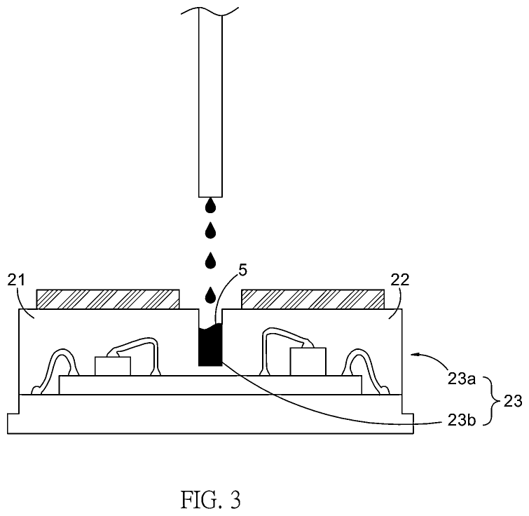

Please refer to FIG. 3, which shows the step of filling opaque glue material 5 by glue dispensing into the groove space 23 formed by above-mentioned precut. Preferably, the opaque glue material 5 is liquid at room temperature for dripping the liquid opaque glue material 5 into the groove space 23 without heating or applying pressure. The advantage of this method is that no redundant part will be formed. The sheltering element 4 may be formed without additional cutting or grinding processes.

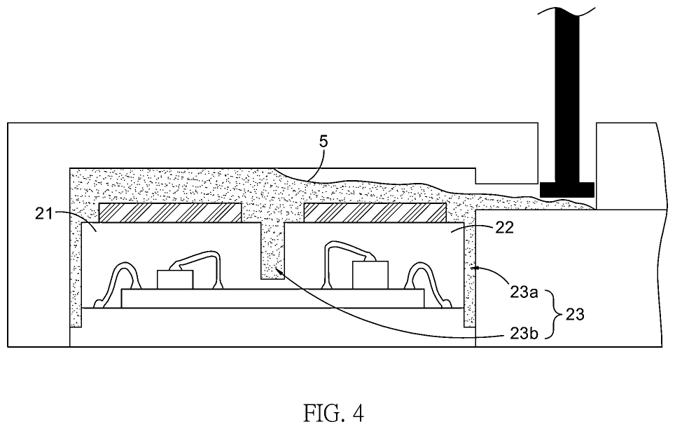

Please refer to FIG. 4, which shows the step of filling opaque glue material 5 by injecting glue via a mold into the groove space 23 formed by precut. The advantage of mold injection is that it is easy to heat and apply pressure. Therefore, it is not required to select liquid materials at room temperature. Besides, no alignment is required for mold injection, making the process speed fast and thus improving the overall fabrication efficiency.

Finally, since the light sensing device packaging structure preferably adopts the panelization process, the sheltering element 4 and the substrate 10 may be cut to form independent products.

To sum up, the first embodiment of the present invention provides a light sensing device packaging structure and the packaging method thereof. By fixing the glasses on the transparent molding substance, the problem of difficulty in fixing the glasses on the cover according to the prior art is effectively avoided. Moreover, by fixing the glasses on the transparent molding substance and disposing the sheltering element on the outside of the transparent molding substance and the glasses, the position of the glasses may be effectively fixed. Therefore, the glasses will not fall off as easily as in the prior art. Accordingly, the light sensing device packaging structure and the packaging method thereof according to the first embodiment of the present invention may maintain excellent light sensing effects of the light sensing device and achieve the purpose of miniaturizing the overall structure.

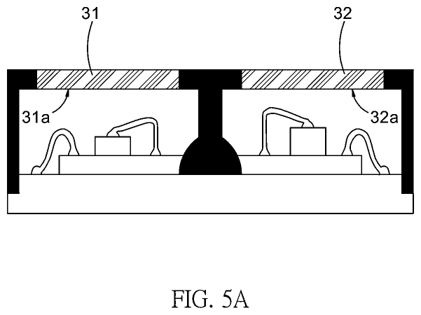

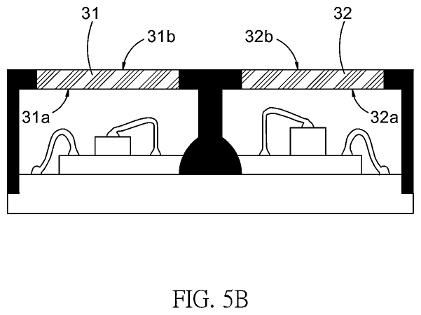

It should be noted that, as described above, the easiest way to implement an optical filter is to create a single-layer or multi-layer coating on the first glass 31 and the second glass 32, which is additionally explained as follows. After the opaque glue material is solidified, redundant parts may be cut and ground as needed to form the sheltering element 4. The first glass 31 and the second glass 32 are used to make optical filters. If the optical filters are formed by coating the surfaces of the first glass 31 and the second glass 32, there will be a risk of damaging the optical filters by cutting and grinding the solidified opaque glue material. Therefore, please refer to FIG. 5A. In this case, it is recommended to form optical filters by coating only the bottom surface 31a of the first glass 31 and the bottom surface 32a of the second glass 32.

Alternatively, please refer to FIG. 5B. If one chooses a method that can form the sheltering element 4 without cutting and grinding the opaque glue material (such as the aforementioned glue dispensing process), or if the user determines that cutting and grinding the opaque glue material will not damage the optical filters, the optical filters may still be formed by coating on an upper surface 31b of the first glass 31 and an upper surface 32b of the second glass 32.

In the following section, the additional benefits of the light sensing device packaging structure and the packaging method thereof according to the present invention will be further illustrated.

As described above, as the size of the sensor shrinks, the structure of the cover and the glass will also be miniaturized. For the miniaturized glass structure, whether it is to be assembled into the cover or other miniaturized structures, the manufacturing process will become more difficult. Consequently, the technical effects achieved by applying embodiments of the present invention to miniaturized sensors are particularly significant. Furthermore, the number of glass structures that need to be assembled will also affect the difficulty of the assembly process. Therefore, the technical effects obtained by applying the embodiments of the present invention are particularly significant for sensors that need to use more glass structures (for example, the light sensing device having multiple light emitting devices and photosensitive devices concurrently).

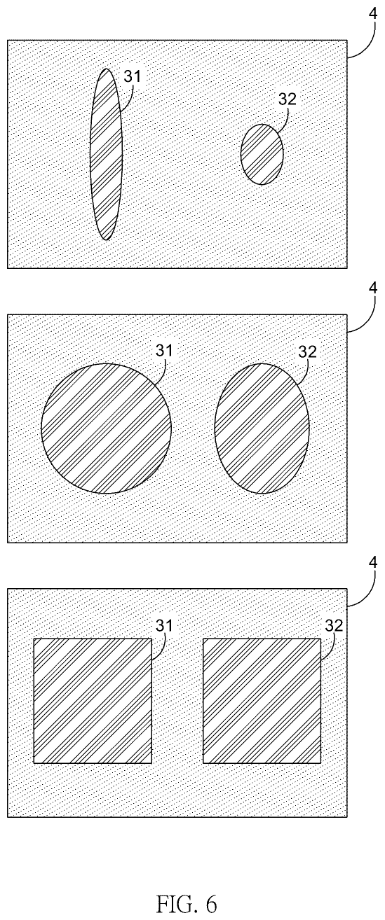

In addition to the impact of size and quantity, the shape and consistency of the glass structure will also affect the process complexity of assembling it to the cover or other miniaturized structures. However, please refer to FIG. 6. For the light sensing device packaging structure and the packaging method thereof according to the embodiment of the present invention, the glass structure is fixed on the transparent molding substance before manufacturing the sheltering element. Accordingly, regardless of the glass shape and whether the structures of the individual glasses are consistent or not, it does not affect the implementation of the embodiments of the present invention. In contrast, according to the prior art, the complexity of the manufacturing process has to be taken into consideration. Therefore, the implementation of the present invention has obvious advantages.

Please continue to refer to FIG. 1. Because the embodiment of the present invention directly fixes the glass structures 31 and 32 to the transparent molding substance 2, there is no gap between the glass structures 31 and 32 and the transparent molding substance 2. In contrast, other prior art that also include a transparent molding substance mostly fix the glass structure on the cover or other components that are separate from the transparent molding substance, resulting in a gap between the glass structure and the transparent molding substance in the prior art. The existence of the gap and the uncertainty of its size may affect the optical sensing effect of the prior art designs. In comparison, the optical sensing device packaging structure and packaging method thereof according to the embodiments of the present invention do not have such problems. Therefore, they may preserve excellent optical sensing effects to the greatest extent possible.

In addition, please continue to refer to FIG. 2. While performing the precutting step to form the second groove space 23b for the wall 41 in the transparent molding substance 2, cutting too deeply might damage the first optical element 11 and the second optical element 12. Therefore, one solution is to reserve a certain amount of transparent molding substance 2 without cutting; another solution is to refer to the Taiwan Patent No. 1779739 applied for by the present applicant to form an opaque material 41a that can completely prevent light from transmission between the first optical element 11 and the second optical element 12. Since this is not the technical content of the present invention, it will not be described further here.

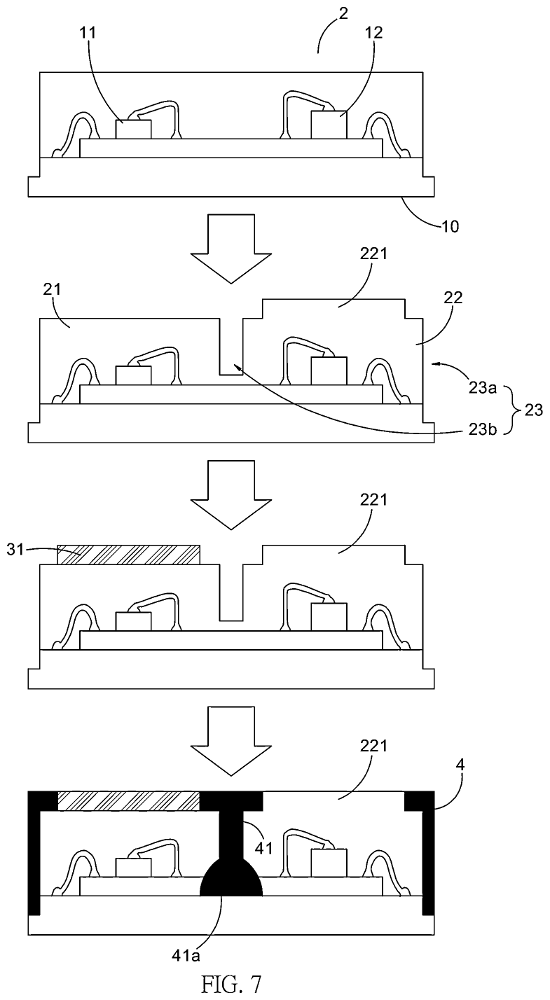

Finally, please refer to FIG. 7, which shows a cross-sectional view of the light sensing device packaging structure according to the second embodiment of the present invention. In the aforementioned light sensing device packaging structure and the packaging method thereof according to the first embodiment of the present invention, the first optical element 11 and the second optical element 12 include the corresponding first glass 31 and the corresponding second glass 32, respectively. However, a person having ordinary skill in the art will understand that in some cases, the second optical element 12 may not require an optical filter, and therefore it is not necessary to provide the second glass 32 for it. Hence, to further reduce costs, in the second embodiment of the present invention, only the first glass 31 is required to correspond to the first optical element 11. Correspondingly, to avoid dents in the light sensing device packaging structure, a convex part 221 is retained at the position aligned with the second optical element 12 (namely, the position of the second glass 32 in the first embodiment) when the transparent molding substance 2 is precut. In this way, when the second glass 32 is omitted, the other parts of the light sensing device packaging structure and the packaging method thereof according to the second embodiment of the present invention may remain unchanged.

To summarize, the light sensing device packaging structure and the packaging method thereof according to the present invention provide a light sensing device packaging structure with glass. By fixing the glass on the transparent molding substance, it effectively avoids the problem of difficulty in fixing the glass on the cover in the prior art, and prevents the glass from easily falling off as in the prior art. It can maintain the excellent optical sensing effect of the light sensing device and achieve the purpose of miniaturizing the overall structure.

The foregoing description presents only embodiments of the present invention, and is not intended to limit the scope and range of the present invention. Those equivalent changes or modifications made according to the shape, structure, feature, or spirit described in the claims of the present invention are included in the appended claims of the present invention.

1. A light sensing device packaging structure, comprising:
a substrate, disposing a first optical element and a second optical element thereon;
a transparent molding substance, covering said first optical element and said second optical element;
a first glass, having a bottom surface fixed on said transparent molding substance and aligned with said first optical element; and
a sheltering element, covering the edge of said transparent molding substance not covered by said first glass.

2. The light sensing device packaging structure of claim 1, wherein said sheltering element includes a wall formed between said first optical element and second optical element.

3. The light sensing device packaging structure of claim 1, wherein said transparent molding substance is divided to a first part and a second part by said wall; said first part covers said first optical element; said first glass is fixed on said first part; and the second part covers said second optical element.

4. The light sensing device packaging structure of claim 1, wherein said first glass is provided to manufacture an optical filter.

5. The light sensing device packaging structure of claim 4, wherein the bottom surface of said first glass forms said optical filter by coating layers.

6. The light sensing device packaging structure of claim 1, further comprising a second glass, having a bottom surface fixed on said transparent molding substance and aligned with said second optical element, and said sheltering element covering the edge of said transparent molding substance not covered by said first glass and said second glass.

7. The light sensing device packaging structure of claim 6, wherein said sheltering element includes a wall formed between said first optical element and second optical element.

8. The light sensing device packaging structure of claim 7, wherein said transparent molding substance is divided to a first part and a second part by said wall; said first part covers said first optical element; said first glass is fixed on said first part; the second part covers said second optical element; and said second glass is fixed on said second part.

9. The light sensing device packaging structure of claim 6, wherein said first glass and said second glass are provided to manufacture optical filters.

10. The light sensing device packaging structure of claim 9, wherein the bottom surface of said first glass and the bottom surface of said second glass form said optical filters by coating layers.

11. A light sensing device packaging method, comprising steps of:
disposing a first optical element and a second optical element on a substrate;
covering said first optical element and said second optical element within a transparent molding substance;
precutting said transparent molding substance to create a groove space;
fixing a bottom surface of a first glass on said transparent molding substance and aligning with said first optical element; and
filling an opaque glue material into said groove space and solidifying said opaque glue material to form a sheltering element;
where said sheltering element covers the edge of said transparent molding substance not covered by the first glass.

12. The light sensing device packaging method of claim 11, wherein said precutting step includes disposing a second groove space in said transparent molding substance for forming a wall of the sheltering element; said second groove space dividing said transparent molding substance to a first part and a second part by said wall; said first part covers said first optical element; said first glass is fixed on said first part; and the second part covers said second optical element.

13. The light sensing device packaging method of claim 11, wherein said first glass is fixed on said transparent molding substance by a transparent glue material.

14. The light sensing device packaging method of claim 11, wherein after solidifying said opaque glue material, the redundant part of said opaque glue material is cut and ground to form said sheltering element.

15. The light sensing device packaging method of claim 11, further comprising a step of cutting said sheltering element and said substrate to make said light sensing device packaging structure be formed independently.

16. The light sensing device packaging method of claim 11, further comprising a step of manufacturing an optical filter on said first glass.

17. The light sensing device packaging method of claim 11, further comprising steps of fixing a bottom surface of a second glass on said transparent molding substance and aligned with said second optical element, and said sheltering element covering the edge of said transparent molding substance not covered by said first glass and said second glass.

18. The light sensing device packaging method of claim 17, wherein said precut step includes disposing a second groove space in said transparent molding substance for forming a wall of the sheltering element; said second groove space dividing said transparent molding substance to a first part and a second part by said wall; said first part covers said first optical element; said first glass is fixed on said first part; the second part covers said second optical element; and said second glass is fixed on said second part.

19. The light sensing device packaging method of claim 17, further comprising a step of manufacturing optical filters on said first glass and said second glass.

20. The light sensing device packaging method of claim 19, wherein the bottom surface of said first glass and the bottom surface of said second glass form said optical filters by coating layers.
